(19) United States
(12) Patent Application Publication
(10) Pub. No.: US 2012/0217042 A1
(43) Pub. Date: Aug. 30, 2012

(54) DEVICE FOR REFLECTING ACCELERATED ELECTRONS

(75) Inventors: Dieter Leffler, Dresden (DE); Olaf Roeder, Dresden (DE); Christoph Kleemann, Neuhausen/Erzg. (DE); Joerg Kubusch, Dresden (DE); Ludwig Forberger, Dresden (DE)

(73) Assignees: ROBERT BOSCH GMBH, Stuttgart (DE); FRAUNHOFER-GESELLSCHAFT ZUR FOERDERUNG DER ANGEWANDTEN FORSCHUNG E.V., Muenchen (DE)

(21) Appl. No.: 13/503,995

(22) PCT Filed: Aug. 25, 2010
(86) PCT No.: PCT/EP2010/005217

§ 371 Date: Apr. 25, 2012

(30) Foreign Application Priority Data
Oct. 30, 2009 (DE) 10 2009 051 374.4

(51) Int. Cl. H05K 1/00

(52) U.S. Cl. 174/250

(57) ABSTRACT

The invention relates to a device by means of which accelerated electrons emitted by an electron source can be reflected onto a surface region of an object (2), comprising at least one dielectric base body (30) on which at least one electrically conductive layer (39) is applied at least in one surface region (A; B), wherein at least one electrically conductive contacting element (31) extends from the electrically conductive layer (39) through the dielectric base body (30).

The invention relates to a device for reflecting electrons onto the surface of an object, which is to be acted on with accelerated electrons for the purpose of property modification.

From the prior art a large number of applications are known in which the surface of an object, an edge layer of an object or even an entire object volume is to be acted on with accelerated electrons in order to change properties of the object. Thus, for example, accelerated electrons are used to destroy germs and microorganisms adhering to bulk seeds, to sterilize medical or pharmaceutical products or in the property modification of plastics and oils.

In most cases of application, an object to be modified is guided past a rigidly arranged electron source and during this is acted on with the accelerated electrons emitted by the electron source. In particular with large-volume objects, all of the surface regions or the entire object volume is not acted on with electrons when the object is guided past once. Therefore devices are known in which either an object is guided past at least once electron source several times with intermediate change of position of the object, as well as devices in which several electron sources are arranged around the object volume, whereby an object can be acted on by electrons over the entire surface in only one pass and without a change of position.

It is likewise known in electron beam processes to use reflectors in order to reflect electron beams aimed past the object in the direction of the object surface and/or to reflect electrons onto those surface regions of an object that do not lie in the direct active region of the electron source.

In DE 198 16 246 C1 a device is described in which a lacquer layer applied on an object is acted on with accelerated electrons. The object has a 90° angle so that one face of the object is aligned parallel and one face of the object is aligned perpendicular to the electron exit window of an electron source. At the side of the electron exit window, a foldable reflector is arranged, by means of which a part of the electrons exiting from the window is reflected onto the object surface aligned perpendicular to the electron exit window. However, the specification does not disclose any other information on the structure and materials of the reflector.

From WO 2007/107331 A1 a device is known in which a molded part is moved between two shaped beam generators for the purpose of sterilization and during this can be acted on with accelerated electrons. This device has several reflectors of gold with which edge beams emitted by the shaped beam generators are reflected on surface regions of the molded part that do not lie in the immediate active region of the shaped beam generators. The reflectors at the same time are part of a sensor system. Connected to measuring devices, by means of the reflectors electron flows can be detected and, as a result of this, conclusions can be drawn on the electron flow density distributions. Since the reflectors known from this specification are made of pure gold, devices of this type are very cost-intensive and thus impair the economical nature thereof. Solutions for whether and how the proportion of reflection and transmission of the electrons striking a reflector can be adjusted, cannot be derived from this specification.

### OBJECT

The invention is therefore based on the technical problem of creating a device for reflecting accelerated electrons, by means of which disadvantages of the prior art can be overcome, not least also with respect to the cost-effectiveness thereof. In particular with the device it should be possible to reflect electrons emitted by an electron source onto the surface of an object to be modified by means of accelerated electrons. Furthermore, it should be possible to use the device as a component of a sensor system for determining electron flows and electron flow density distributions. Likewise, solutions are to be disclosed for how the proportion of reflection and transmission of the electrons striking a reflector can be adjusted.

The solution of the technical problem is shown by objects with the features of claim 1. Further advantageous embodiments of the invention are shown by the dependent claims.

A device according to the invention, by means of which accelerated electrons emitted by an electron source can be reflected onto a surface region of an object, comprises at least one dielectric base body on which at least one electrically conductive layer is applied at least in one surface region, on which layer a proportion of the accelerated electrons emitted by the electron source and striking the electrically conductive layer can be reflected. For the purpose of contacting the electrically conductive layer, at least one electrically conductive contacting element extends from the electrically conductive layer through the dielectric base body. Due to the impingement of the electrically conductive layer with accelerated electrons, a charge carrier surplus builds up thereon and thus an electric voltage with respect to the electric mass. A measuring device can therefore be connected between the contacting element and the electric mass, by means of which measuring device an electron flow can be detected. The electrons accelerated by the electron source (also referred to as an electron accelerator) onto the electrically conductive layer are thus reflected in a first proportion by the electrically conductive layer and are involved with a second proportion in the flow of an electric current from the electrically conductive layer through the contacting element. As is explained below, the ratio of the two proportions can be changed or adjusted.

With a once fixedly adjusted proportion of the reflected electrons, depending on the detected electric current a qualitative conclusion can then be drawn on the energy or energy dose with which a surface region of an object is acted on, onto which the accelerated electrons are reflected by the electrically conductive layer. The higher the detected electric current, the higher the energy or the energy dose with which the surface region of the object is impinged.

With a device according to the invention therefore on the one hand accelerated electrons emitted by an electron source can be reflected and on the other hand a device according to the invention can be used as a component of a sensor system or a measurement system with which conclusions can be drawn about the energy with which an object is impinged.

Usually the surface region of the dielectric base body, within which the electrically conductive layer is located, is embodied in a flat manner, the dielectric base body itself being embodied in a plate-like manner. However, depending on the case of application and/or depending on the shape of the object to be modified with electron energy, this surface region can also have another geometric shape. Thus this surface region for instance can be embodied in a concave manner with a convex object, or vice versa.

If several devices according to the invention are arranged next to one another within a spatial dimension and for each device an electric current is detected which flows from the respective electrically conductive layer through an associated contacting element, depending on the individually detected electric currents a qualitative conclusion can also be drawn on the distribution of the energy with which the object is acted on within the spatial dimension. Of course, this qualitative conclusion is more accurate, the more devices according to the invention are arranged next to one another in a spatial dimension and the more electric currents accordingly are detected.

Alternatively to the embodiment that a dielectric base body has only one surface region with an electrically conductive layer, a dielectric base body can also have several surface regions within which an electrically conductive layer is embodied, wherein the individual electrically conductive layer regions are embodied electrically insulated from one another and wherein each electrically conductive layer region has at least one contacting element that extends from the associated electrically conductive layer region through the dielectric base body. Each contacting element is then connected to an associated measuring device for detecting an electric current. With an embodiment of this type, as many electrically conductive layer regions as desired can be arranged in a one-dimensional or also two-dimensional manner next to one another on the surface of a dielectric base body.

With a device according to the invention in which respectively at least two electrically conductive layer regions are embodied on a flat surface of a dielectric base body in two dimensions, through the evaluation of the respectively detected electric currents that flow over the electrically conductive layer regions, a two-dimensional statement can be made regarding the distribution of the electron energy with which an object to be modified is impinged. The previous description also applies here: the more and the more densely the electrically conductive layer regions are arranged next to one another in a spatial dimension, the higher the local resolution of the current density of an electron beam and the more accurate the statements that can be made regarding the distribution of the energy with which the surface of an object is impinged.

The dielectric base body acts essentially as carrier of the electrically conductive layer or of the electrically conductive layer regions and gives the device the necessary mechanical stability. With respect to the material for the dielectric base body, in addition to a necessary strength there is the requirement that it must also be resistant to ionizing radiation. Ceramic materials, for example, are very suitable for this purpose. Ceramics such as aluminum oxide or zirconium oxide are cited by way of example at this point, but all other known ceramics can also be used for this purpose. In addition to ceramic materials, however, glass materials, for example, can also be used for the dielectric base body.

All materials that have an electric conductivity can be used for the at least one electrically conductive layer. When an electron beam strikes the electrically conductive layer, the kinetic energy of the beam electrons is converted by interactions with atoms of the layer material in part into heat or excitation energy of the atoms. The plurality of elastic and non-elastic impacts which the beam electrons carry out with the atoms of the layer material, in addition to a loss of energy, also cause a change in direction of the beam electrons, which is why a proportion of the beam electrons is backscattered and thus reflected by the electrically conductive layer. The intensity distribution of the reflected electrons over the solid angle is embodied in a lobe-shaped manner and has an intensity maximum the direction of which corresponds to the optical reflection law—angle of incidence equals emergence angle. The proportion of backscattered or reflected electrons is determined essentially by the angle of entry of the electron beam and by the atomic number of the elements involved in the layer structure. The flatter the angle of entry of the electron beam on the electrically conductive layer, and the higher the atomic number of the elements involved in the layer structure, the higher the proportion of reflected beam electrons. Since the reflection of beam electrons represents a major function with a device according to the invention, for the electrically conductive layer those electrically conductive materials are particularly suitable which are composed of one element or of several elements that have a high atomic number. In one embodiment the electrically conductive layer is therefore composed of one or more element(s) from the group of the elements with an atomic number of 40 through 79.

Due to the thermal effects of accelerated electrons striking the electrically conductive layer, it is furthermore advantageous if the material used for the electrically conductive layer has a melting temperature of more than 1000°. However, materials with a lower melting temperature as low as 200° can also be used for the electrically conductive layer if, for example, only low electron beam powers are used and/or if measures are taken for cooling the electrically conductive layer. Thus, for example, the dielectric base body can be permeated by cooling channels and flowed through by a cooling medium in order to dissipate heat from the electrically conductive layer.

Materials such as gold, tantalum, molybdenum, tungsten or alloys of two or more of the above-mentioned elements are very suitable for an electrically conductive layer of a device according to the invention because these materials have good electrical conductivity as well as a high melting temperature and thus do not require any additional cooling expenditure.

Gold is very particularly suitable for the electrically conductive layer. In addition to a relatively high melting temperature, very good electrical conductivity, a high proportion of reflected electrons due to a relatively high atomic number, gold is also a layer material that can be used in applications in which pharmaceutical or medical products are to be acted on with electrons.

A contacting element which with a device according to the invention extends from an electrically conductive layer through the dielectric base body, is likewise composed of an electrically conductive material. Since a contacting element is not exposed to the direct electron bombardment, there are no high demands as far as its temperature resistance is concerned. Therefore materials such as gold, platinum, titanium, molybdenum, iron, chromium, tantalum or alloys of at least two of the above-mentioned elements are suitable for this. A contacting element is preferably embodied as a pin-shaped contact pin and can have a cross section of any desired geometric shape. It is advantageous if the contact pin has a standardized cross section so that standardized contact means, such as plug and socket connectors, for example, can also be used for contacting the contact pin.

A particular focus is on the incorporation of the contact pin or pins into a dielectric base body. In particular when a device according to the invention is used in the production or processing of pharmaceutical or medical products, there can be very high demands regarding the tightness of the joint between the dielectric base body and the contacting element. In application cases of this type, the reflector according to the invention is often embodied simultaneously as a wall between a space with high sterility and a space with lower sterility, wherein the space with high sterility adjoins the electrically conductive layer and the space with lower sterility adjoins the back of the reflector, that is, the dielectric base body. It must be ensured here that no germs can pass from the space with lower sterility through the joint between the dielectric base body and the contacting element. With the relatively simple means of a gas pressure test, for example, it is possible to check whether a joint is embodied in a gas-tight manner. If a joint is embodied in a gas-tight manner, then in any case it is also ensured that no germs can pass through the joint. In one embodiment of the invention the joint between the dielectric base body and the contacting element is therefore embodied in a gas-tight manner.

Various methods are suitable for the gas-tight incorporation of a contacting element into a dielectric base body. In all of the methods, firstly a hole corresponding to the cross section of the contacting element must be inserted into the dielectric base body, which hole extends through the entire thickness of the dielectric base body and into which the contacting element is inserted. The hole can thereby be embodied with a constant cross section through the entire thickness of the base body, or can also have an enlargement of the cross section towards the back of the base body, which in this thickness range of the base body acts as an expansion space for the contacting element with subsequent processing steps. The contacting element must have a length such that it extends on the one hand through the entire thickness of the dielectric base body and then protrudes so far on the back of the dielectric base body that it can be contacted with contact means, such as with plug and socket connectors, for example. On the side of the dielectric base body on which the electrically conductive layer is applied (in this specification also referred to as the front), the contacting element must extend at least up to the surface of the base body, but can also firstly project a little beyond it during insertion into the dielectric base body.

The material of which a contacting element is composed is in part also determined by the incorporation method. Thus a contacting element for example can be incorporated into a dielectric base body of a ceramic in a gas-tight manner by means of a soldering process. If this incorporation method is used, metals or metal alloys are suitable as a material for the contacting element with which a known ceramic metal solder connection can be produced. A further requirement is that the ceramic used for the dielectric base body and the material for the contacting element have at least approximately a similar coefficient of thermal expansion so that during the heating and subsequent cooling of the soldered connection no mechanical stresses occur in the joint which can lead to crack formation.

Therefore when incorporating a contacting element by means of a soldering process, for example, materials such as molybdenum or a NiCoSil alloy can be used for the contacting element.

An alternative approach in the incorporation of a contacting element into a ceramic dielectric base body is sintering, i.e., the contacting element is incorporated into the dielectric base body directly during the firing of the ceramic. For example, platinum, tungsten, titanium or alloys of the aforementioned elements can be used as materials for the contacting element with this incorporation process.

As a further alternative for the incorporation of a contacting element, an adhesive process can be selected in which all of the previously referenced materials can also be used for a contacting element. If a gas-tight adhesive connection between the dielectric base body and the contacting element is to be produced hereby, however, it is not sufficient to use a purely organic adhesive because this is degraded under the influence of ionizing radiation, whereby the joint on the one hand loses its strength and on the other hand can become permeable for gases or for germs.

It is therefore advantageous to add solid particles, such as ceramic particles, for example, to an adhesive. It has been shown that despite the degrading of the organic adhesive constituents in the joint under the influence of ionizing radiation, the remaining solid particles ensure both the necessary retention of the contacting element as well as a necessary tightness of the joint.

If the at least one contacting element is fixedly incorporated into the dielectric base body, the side of the dielectric base body on which the electrically conductive layer is to be applied and from which the contacting element can protrude a little after insertion, is ground smooth such that the surface of the dielectric base body forms a flat surface with the end of the contacting element, on which flat surface subsequently the at least one electrically conductive layer is applied. The finer the finish, the more durable the electrically conductive layer, since coating errors are minimized. In one embodiment the ground surface therefore has a roughness of less than 0.05. The electrically conductive layer and the contacting element form an electrically conductive connection after the application of the electrically conductive layer.

Different methods can also be used for the application of the at least one electrically conductive layer. Vacuum methods of chemical or physical steam separation, for example, are suitable for applying the electrically conductive layer in its full thickness or for applying initially only a partial layer of the electrically conductive layer which can subsequently be strengthened by means of an electrodeposit method. However, the electrically conductive layer can also be deposited entirely by means of galvanic methods. A further alternative method for applying the electrically conductive layer lies in applying a paste in which conductive particles are mixed onto the dielectric base body before the sintering of a ceramic dielectric base body. After a sintering operation, a layer of the conductive particles then remains on the surface of the dielectric base body. A gold-containing paste can be used for this purpose, for example, of which a gold layer remains on the surface of the dielectric base body after a sintering operation. In a further alternative exemplary embodiment, the paste with conductive particles can also be applied to the dielectric base body only after the sintering.

As already mentioned, with a device according to the invention the proportion of the electrons reflected by the electrically conductive layer can be adjusted. The selection of the applied layer thickness of the electrically conductive layer (hereinafter also referred to as reflection layer) in combination with the selection of the layer material makes it possible to exactly adjust the proportion of reflected electrons to the transmission proportion. If the total layer thickness of the reflection layer is at least just as large as the maximum penetration depth of the accelerated electrons, this ensures that a maximum proportion of the electrons is also reflected. The proportion of electrons available for the measurement signal is correspondingly small. The proportion of reflected electrons is also reduced to the same extent that the layer thickness of the reflection layer (starting from a layer thickness that corresponds to the maximum penetration depth of the electrons) is reduced, whereas the transmission proportion, that is, the proportion of electrons available for the measurement signal, is increased. For the sake of completeness, it should be noted here that the impingement of accelerated electrons on the electrically conductive layer in addition to backscattered or reflected electrons and the flow of an electric current from the electrically conductive layer, via a contacting element to a measuring device also causes the release of secondary electrons and of thermal electrons as well as the generation of thermal radiation and X-ray radiation. With respect to the device according to the invention, however, only the facts of the reflected electrons and the current flow are considered in greater detail.

The maximum penetration depth of accelerated electrons into a material depends on various factors due to the kinetic energy thereof, but can be determined by means of known formulas or from known tables and charts. Thus depending on the object, that is, depending on whether more electrons are to be reflected or whether more electrons are to be available for the measurement signal, a thickness for the reflection layer can be determined in advance and the ratio of the electrons available for reflection and transmission can thereby be adjusted.

In one embodiment for predominant reflection of the accelerated electrons, the layer thickness d_{R} of the reflection layer is adjusted in a range that is greater than the maximum penetration depth of the electrons and is shown by the following formula:

$${d}_{R} = s * \frac{6 , 67 * {10}^{- 1} \frac{{( Ub * {k}_{1} )}^{5.3}}{{ρ}_{W}} * {k}_{2} - {ρ}_{F} * {d}_{F}}{{ρ}_{G}}$$

Ub=acceleration voltage

ρ_{W}=density of water

ρ_{G}=density of the reflection layer

ρ_{F}=density of the window film of the electron accelerator

d_{F}=thickness of the window film of the electron accelerator

k₁=1*V⁻¹

k₂=1*(g/m²)²*m⁻¹

s=safety factor (s≧1.5).

With a device according to the invention, the electrically conductive layer can also be composed of two or more partial layers. For better adhesion of the cover layer acting as the actual reflection layer, for example, one or more partial layers can be arranged under the reflection layer, which act as adhesion promoter layer(s) between the dielectric base body and the reflection layer. Furthermore, at least one partial layer can also be embodied as a barrier layer in order to prevent particles from an adhesive layer and/or from the dielectric base body from diffusing into the reflection layer. One requirement of a partial layer acting as an adhesion promoter layer and of a partial layer acting as a barrier layer, however, lies in that they must be electrically conductive so that an electric current can flow from the reflection layer to the contacting element. Thus a partial layer of the electrically conductive layer embodied as an adhesion promoter layer can be composed of one or more elements of the group chromium, manganese, iron, cobalt, and materials containing platinum, tantalum, gold or titanium can be used for a partial layer embodied as a barrier layer.

### EXEMPLARY EMBODIMENT

The invention is explained in more detail below based on a preferred exemplary embodiment. Components that have the same reference numbers in different figures correspond in terms of function or structure. The figures show:

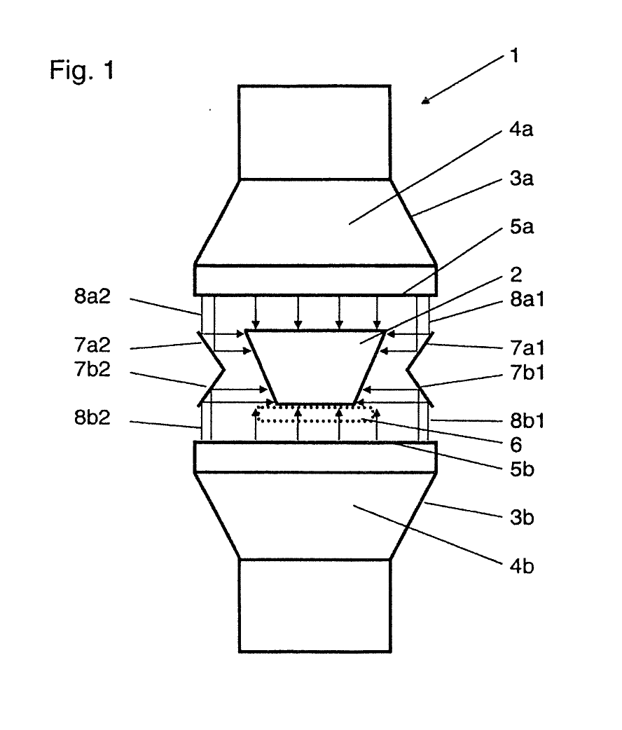

FIG. 1 A diagrammatic representation of a device for acting on an object with accelerated electrons;

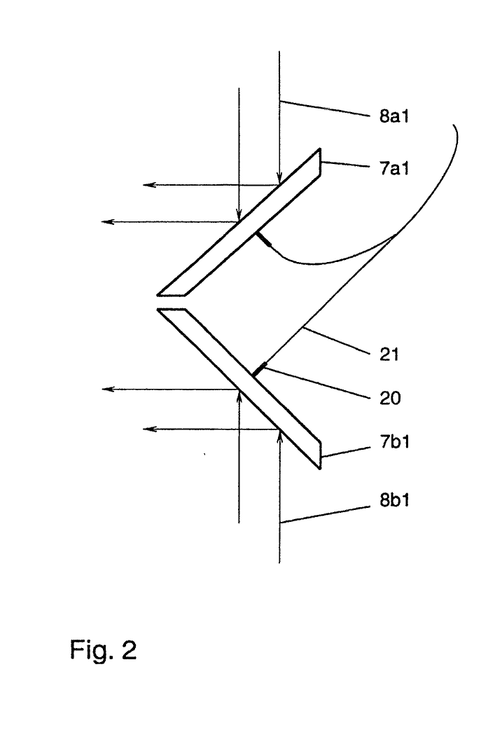

FIG. 2 A diagrammatic representation of a reflector group of the device from FIG. 1;

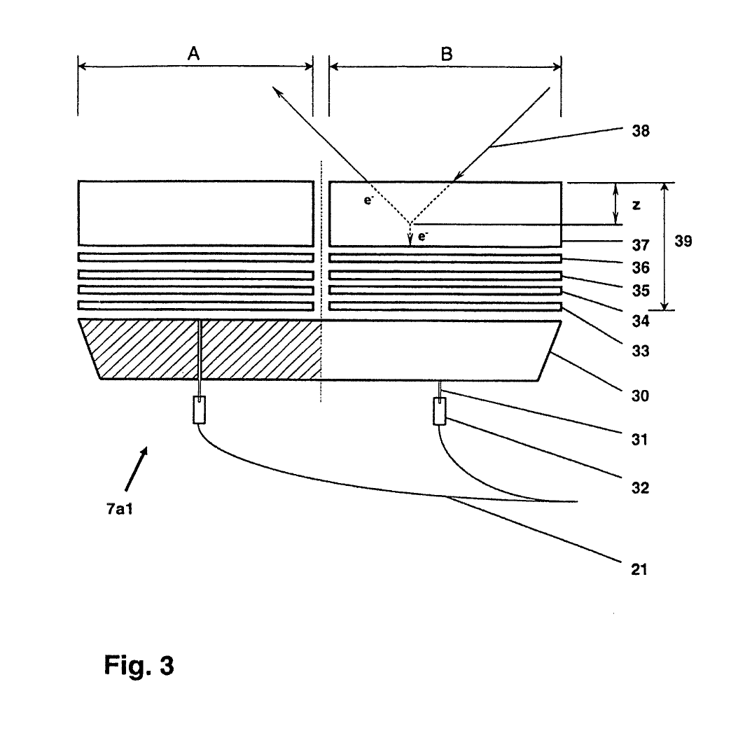

FIG. 3 A diagrammatic representation of the structure of a reflector of the reflector group from FIG. 2;

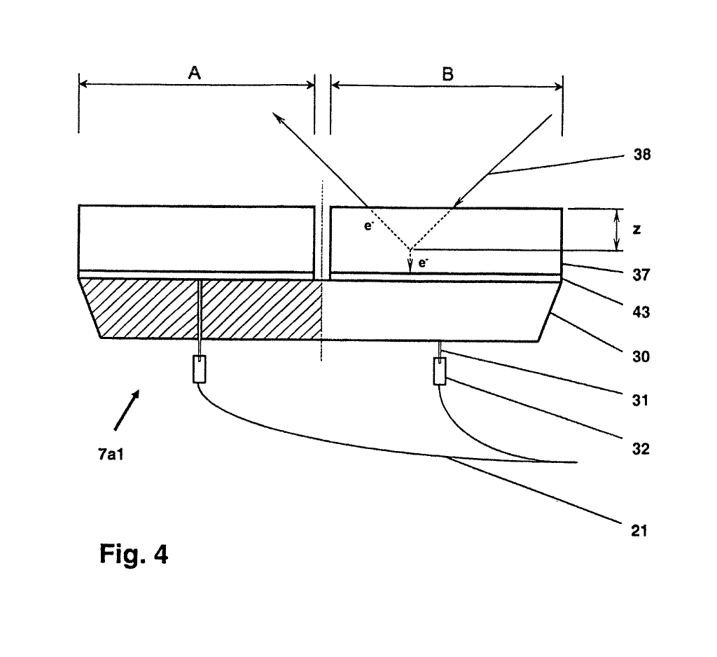

FIG. 4 A diagrammatic representation of an alternative structure of a reflector of the reflector group from FIG. 2.

FIG. 1 shows a device 1 diagrammatically in cross section, by means of which the surface of a molded part 2 can be acted on with accelerated electrons in order to sterilize the surface of the molded part 2. The molded part 2 is an elongated object with a trapezoidal cross section. The device 1 is composed of two electron accelerators 3a, 3b embodied as shaped beam generators, which respectively comprise an electron acceleration chamber 4a, 4b and an electron exit window 5a, 5b. The electron exit windows are hereby embodied respectively as a titanium film 11 μm thick. The electron accelerators 3a, 3b are arranged such that the electron exit windows 5a, 5b shaped in a flat manner are aligned parallel opposite one another. Between the two electron exit windows 5a, 5b the molded part 2 is guided continuously on a conveyor belt system 6 interrupted at the height of the electron exit window 5b and shown by a dotted line in FIG. 1 in the direction of the image depth and the entire surface of which is thereby impinged with electron energy. In each case the lowest energy dose would be transmitted to the points furthest removed from the electron exit windows on the oblique side surfaces of the molded part 2 thereby, which is compensated by the arrangement of electron reflectors 7a1, 7b1, 7a2, 7b2 (hereinafter referred to merely as reflector(s)). This takes place in that the unused edge beams 8a1, 8a2, 8b1, 8b2 of the respective electron beam of the two electron accelerators 3a, 3b strike the respectively nearest reflector, are reflected there and are guided by the angular arrangement of the reflectors into the region of the lowest dose onto the molded part. From a total arrangement of this type, an energy dose results on the entire surface or also in an entire edge layer of the molded part with a minimum overdose factor, a maximum utilization of the electron flow and a minimum of reactive ozone produced in the air gap.

FIG. 2 shows the reflector group 7a1, 7b1 in a somewhat more detailed diagrammatic representation. It is discernible that the reflectors 7a1, 7b1 on the one hand are spaced apart from one another and thus do not have any electrical contact to one another and on the other hand are provided on the back thereof respectively with contact elements 20, to which electric lines 21 are connected, which in turn are connected to a measuring device, not shown in FIG. 2. By means of this measuring device values for electric currents are recorded, which flow through the reflectors 7a1 and 7b1 to the associated contact elements 20. A separate measuring device can hereby be assigned to each contact element 20 or several contact elements 20 are connected to a measuring device that has several measurement inputs.

The structure of the reflectors 7a1, 7a2, 7b1, 7b2 from FIG. 1 is identical and is illustrated diagrammatically based on the reflector 7a1 by way of example in an exploded view. The base of the reflector 7a1 is formed by a dielectric base body 30 of high-density, i.e., at least 99.5% pore-free Al₂O₃, which has a purity of at least 99.5%. The ceramic base body 30 gives the reflector 7a1 its mechanical stability. It is embodied in a plate-like manner and has a plate thickness of 12 mm. The horizontal extension of the reflector 7a1 in FIG. 3 corresponds to the extension that the reflector 7a1 has in FIGS. 1 and 2 in the image depth. It can furthermore be seen from FIG. 3 that a contact element 20 according to FIG. 2 is composed of two separate components, a contact pin 31 of platinum and a contact sleeve 32. Each base body 30 is provided with two contact pins 31, which respectively extend through the entire plate thickness of the base body 30, as can be seen from the left half of the base body 30 in FIG. 3, which is shown there in a sectional representation. Before the sintering of the base body 30, the contact pins 31 had already been inserted into the material thereof, namely such that a contact pin 31 on the one hand extends completely through the entire plate thickness of the base body 30 and on the back of the base body projects so far that another contact sleeve 32 can be fitted on the projecting end of the contact pin 31. Alternatively, a contact sleeve 32 can also be clamped, screwed or attached in any other known manner to a contact pin 31.

During the sintering of the base body 30, the contact pins 31 inserted into the raw material of the base body are firmly incorporated into the material of the base body and a gas-tight connection is produced thereby at the joints between the contact pin and the base body. After the sintering, the front of the base body 30 is ground smooth so that the ends of all of the contact pins 31 form a flat surface with the front of the base body 30.

After the front of the base body has been ground smooth, two identical layer stacks are applied in surface areas A and B thereon, wherein the two layer stacks are embodied electrically insulated from one another, however. This requirement can be implemented in that, for example, one or more layers are applied over the entire area on the front, wherein subsequently, for example, by an etching method a separation is made between the two layer regions. Alternatively, the layer regions electrically insulated from one another can also be applied separately by means of a mask on the front of the base body.

As has already been described above, in addition to a dielectric base body with embedded contact pin, a reflector according to the invention also comprises an electrically conductive layer. In the exemplary embodiment the electrically conductive layer 39 is composed of several partial layers deposited one on top of the other. The cover layer of the layer stack, which acts as the actual reflection layer, is to be embodied as a gold layer in the exemplary embodiment. Because a gold layer does not have a very good adhesion on a ceramic body of Al₂O₃, firstly an electrically conductive adhesive layer 33 of chromium 100 nm thick is deposited on the smoothly ground front of the base body 30 by means of a vacuum coating method. However, chromium particles from the adhesive layer 33 can diffuse into and through an adjoining gold layer and oxidize on the surface thereof which can have negative effects in the case of uses in the medical and pharmaceutical field. Therefore first an electrically conductive diffusion barrier layer 34 of titanium 200 nm thick and subsequently an electrically conductive diffusion barrier layer 35 of platinum 500 nm thick are likewise deposited onto the adhesive layer 33 by means of a vacuum coating method. Because of the better adhesion, subsequently a gold layer 36 1000 nm thick is applied again by means of a vacuum coating method on the platinum layer 35, which gold layer subsequently is finally strengthened by electroplating with a gold layer 37 at least 22 μm thick, because quicker layer thickness increases with closed surface structure can be realized by means of electrodeposit methods. The electrically conductive layer 39, which is located on a dielectric base body in the case of a device according to the invention, in the exemplary embodiment thus comprises the partial layers 33, 34, 35, 36 and 37, wherein the partial layers 36 and 37 of gold act in combination as the actual reflection layer.

A proportion of the electrons of the electron beam 38, which strikes the gold layer (composed of the partial layers 37 and 36) in the region A or B, are partially reflected on or inside the gold layer. A proportion of the non-reflected electrons causes a current flow from the gold layer through the likewise electrically conductive layers 35, 34 and 33 to the associated contact pin 31. This electric current flows further via the contact sleeve 32 and through the electric line 21 connected thereto to the measuring device, not shown, in which values for the flowing electric current are recorded.

The electrons of the electron beam 38 striking the gold layer can penetrate up to a maximum depth z into the gold layer due to their kinetic energy. In the exemplary embodiment, in which it is important to reflect beam electrons onto the surface of an object, the thickness of the gold layer (composed of the partial layers 37 and 36) is sized such that it is larger than the maximum penetration depth z. As a result, a large proportion of beam electrons is reflected from the gold layer.

If the thickness of the gold layer is embodied to be smaller than the penetration depth z, a proportion of the beam electrons would reach the conductive layers 35, 34 and 33 lying below the gold layer and up to the dielectric base body 30. The kinetic energy of this proportion of electrons would then no longer be sufficient for a reflection, so that this proportion of electrons flows via the electrically conductive layer 33 to the associated contact pin 31, via the contact sleeve 32 and through the electric line 21 connected thereto to the measuring device, not shown, in which values are recorded for the flowing electric current. In this embodiment, the proportion of reflected electrons would therefore be smaller than with the embodiment previously described, in which the thickness of the gold layer is larger than the penetration depth z.

FIG. 4 shows diagrammatically an alternative structure of the reflector 7a1. This variant also comprises a dielectric base body 30 of aluminum oxide with embedded contact pins 31, the contact sleeve 32 fitted thereon with associated electric line 21, which leads to a measuring device, not shown. Before the sintering of the base body 30, it was coated in the regions A and B with a paste containing gold, comprising gold particles and a sinterable binder. During the sintering process, the gold particles contained in the paste are firmly incorporated into the surface of the base body 30 or bonded firmly onto the surface of the base body 30 with the aid of the binder and thus form a gold-containing layer 43, on which in a subsequent process step a gold layer at least 22 μm thick is electrodeposited, which then has a high adhesion to the base body. Before the application of the gold layer to be electrodeposited, the surface of the base body can be ground smooth on the front thereof, as described for FIG. 3, so that the contact pins possibly protruding from the base body are shortened to the height of the flat surface of the base body. However, it must be ensured hereby that, despite the greatest possible minimization of roughness of the surface by means of grinding, the gold particles burnt into the surface of the base body during sintering are not removed again, because otherwise the adhesion of the gold layer subsequently electrodeposited is negatively impaired.

1. A device by means of which accelerated electrons emitted by an electron source can be reflected onto a surface region of an object (2), comprising at least one dielectric base body (30) on which at least one electrically conductive layer (39) is applied at least in one surface region (A; B), wherein at least one electrically conductive contacting element (31) extends from the electrically conductive layer (39) through the dielectric base body (30).

2. The device according to claim 1, characterized in that the dielectric base body (30) is composed of a ceramic or of glass.

3. The device according to claim 2, characterized in that the ceramic is aluminum oxide or zirconium oxide.

4. The device according to claim 1, characterized in that the electrically conductive layer (39) at least on the surface thereof is composed of a material that has at least one of the elements gold, tantalum, molybdenum, tungsten.

5. The device according to claim 4, characterized in that the electrically conductive layer is embodied as a gold layer at least 5 μm thick.

6. The device according to claim 1, characterized in that the electrically conductive layer (39) on the surface of the dielectric base body (3) is divided into several layer regions (A; B), which are embodied electrically insulated from one another and wherein at least one contacting element (31) is assigned to each layer region (A; B), which contacting element extends from the respective layer region (A; B) of the electrically conductive layer (39) through the dielectric base body (30).

7. The device according to claim 1, characterized in that the electrically conductive layer (39) is composed of at least two partial layers (33; 34; 35; 36; 37) deposited one on top of the other.

8. The device according to claim 7, characterized in that at least one partial layer (33) is embodied as an adhesion promoter layer.

9. The device according to claim 8, characterized in that the adhesion promoter layer has at least one of the elements of the group chromium, manganese, iron or cobalt.

10. The device according to claim 7, characterized in that at least one partial layer (34; 35) is embodied as a barrier layer.

11. The device according to claim 10, characterized in that the barrier layer has at least one of the elements from the group platinum, titanium, tantalum or gold.

12. The device according to claim 1, characterized in that the contacting element (31) is embodied as a contact pin, the material of which comprises at least one of the elements from the group gold, platinum, titanium, molybdenum, iron, chromium or tantalum.

13. The device according to claim 1, characterized in that the joint between the dielectric base body (30) and the contact pin (31) is embodied in a gas-tight manner.
